(19) United States
(12) Patent Application Publication
(10) Pub. No.: US 2013/0087803 A1
(43) Pub. Date: Apr. 11, 2013

(54) MONOLITHICALLY INTEGRATED HEMT AND SCHOTTKY DIODE

(71) Applicants: Isik C. Kizilyalli, San Francisco, CA (US); Hui Nie, Cupertino, CA (US); Andrew P. Edwards, San Jose, CA (US); Linda Romano, Sunnyvale, CA (US); David P. Bour, Cupertino, CA (US); Richard J. Brown, Los Gatos, CA (US); Thomas R. Prunty, Santa Clara, CA (US)

(72) Inventors: Isik C. Kizilyalli, San Francisco, CA (US); Hui Nie, Cupertino, CA (US); Andrew P. Edwards, San Jose, CA (US); Linda Romano, Sunnyvale, CA (US); David P. Bour, Cupertino, CA (US); Richard J. Brown, Los Gatos, CA (US); Thomas R. Prunty, Santa Clara, CA (US)

(73) Assignee: EPOWERSOFT, INC., San Jose, CA (US)

(21) Appl. No.: 13/267,552

(22) Filed: Oct. 6, 2011

(51) Int. Cl. H01L 29/778; H01L 21/335

(52) U.S. Cl. 257/76; 438/172; 257/194; 257/E29.246; 257/E21.403

(57) ABSTRACT

An integrated device including a III-nitride HEMT and a Schottky diode includes a substrate comprising a first III-nitride material and a drift region comprising a second III-nitride material coupled to the substrate and disposed adjacent to the substrate along a vertical direction. The integrated device also includes a first barrier layer coupled to the drift region and a channel layer comprising a third III-nitride material having a first bandgap and coupled to the barrier layer. The integrated device further includes a second barrier layer characterized by a second bandgap and coupled to the channel layer and a Schottky contact coupled to the drift region. The second bandgap is greater than the first bandgap.

### BACKGROUND OF THE INVENTION

Power electronics are widely used in a variety of applications. Power electronic devices are commonly used as part of a circuit to modify the form of electrical energy, for example, in voltage or current converters. Such converters can operate over a wide range of power levels, from milliwatts in mobile devices to hundreds of megawatts in a high voltage power transmission system). Despite the progress made in power electronics, there is a need in the art for improved electronics systems and methods of operating the same.

### SUMMARY OF THE INVENTION

The present invention relates generally to electronic devices. More specifically, the present invention relates to methods and systems for a high electron mobility field effect transistor (HEMT) monolithically integrated with a Schottky diode. Merely by way of example, the invention has been applied to integration of these structures in III-nitride based materials to provide for high power operation. The methods and techniques can be applied to a variety of compound semiconductor devices including other types of transistors and diodes, as well as other device types such as thyristors.

According to an embodiment of the present invention, an integrated device including a III-nitride HEMT and a Schottky diode is provided. The integrated device includes a substrate comprising a first III-nitride material and a drift region comprising a second III-nitride material coupled to the substrate and disposed adjacent to the substrate along a vertical direction. The integrated device also includes a first barrier layer coupled to the drift region and a channel layer comprising a third III-nitride material having a first bandgap and coupled to the barrier layer. The integrated device further includes a second barrier layer characterized by a second bandgap and coupled to the channel layer and a Schottky contact coupled to the drift region. The second bandgap is greater than the first bandgap.

According to another embodiment of the present invention, an integrated device including a III-nitride HEMT and a Schottky diode is provided. The integrated device includes a substrate comprising a first III-nitride material, a drift region comprising a second III-nitride material coupled to the substrate and disposed adjacent to the substrate along a vertical direction, and a Schottky contact coupled to the drift region. The integrated device also includes a first barrier layer coupled to the drift region and a channel layer comprising a third III-nitride material having a first bandgap and coupled to the barrier layer. The integrated device further includes a second barrier layer characterized by a second bandgap and coupled to the channel layer and a gate region comprising a gate material disposed between the second barrier layer and a gate contact. The second bandgap is greater than the first bandgap.

According to a specific embodiment of the present invention, a method for fabricating an integrated transistor and Schottky diode is provided. The method includes providing a III-nitride structure having a III-nitride substrate, a first III-nitride epitaxial layer coupled to the III-nitride substrate, a second III-nitride epitaxial layer coupled to the first III-nitride epitaxial layer, a third III-nitride epitaxial layer coupled to the second III-nitride epitaxial layer; and a fourth III-nitride epitaxial layer coupled to the third III-nitride epitaxial layer. The method also includes forming an insulating layer coupled to a portion of the fourth III-nitride epitaxial layer and removing at least a portion of the fourth III-nitride epitaxial layer, at least a portion of the third III-nitride epitaxial layer, and at least a portion of the second III-nitride epitaxial layer to expose a portion of the first III-nitride epitaxial layer. The method further includes forming a first ohmic structure electrically coupled to the III-nitride substrate, forming a source ohmic structure electrically coupled to the fourth III-nitride epitaxial layer, forming a gate structure, forming a drain ohmic structure electrically coupled to the fourth III-nitride epitaxial layer, and forming a Schottky contact to the first III-nitride epitaxial layer.

Numerous benefits are achieved by way of the present invention over conventional techniques. For example, embodiments of the present invention provide an electronic switch integrated with a Schottky diode while providing the benefits inherent in GaN-based materials. As an example, embodiments of the present invention provide high-voltage products for which markets exist for switch mode power supplies, power factor correction, dc-ac inverters, dc-dc boost converters, and various other circuit topologies.

An advantage provided by embodiments of the present invention utilizing GaN-based materials (i.e., the group III-nitride (III-N) family) is the ability to form a high electron density, high mobility two dimensional electron gas (2DEG), for example, in a quantum well at the heterointerface between GaN and AlGaN. The 2DEG can be used to form the channel of a HEMT. Such a device can have a very low on-state resistance. The controlling gate may include one of several types including a p-n junction, an MIS capacitor, a Schottky barrier, or the like, each having its own merits.

Another advantage provided by embodiments of the present invention over conventional devices is based on the superior material properties of GaN-based materials. Embodiments of the present invention provide homoepitaxial GaN layers on bulk GaN substrates that are imbued with superior properties to other materials used for power electronic devices. High electron mobility, μ, is associated with a given background doping level, N, which results in low resistivity, ρ, since ρ=1/qμN.

Another beneficial property provided by embodiments of the present invention is a high critical electric field, E_{crit}, for avalanche breakdown. A high critical electric field allows large voltages to be supported over a smaller length, L, than a material with lesser E_{crit}. For the lateral HEMT this results in smaller dimensions such as gate-to-drain spacing. For a high voltage device with the drift region oriented vertically, more unit cells can be packed into an area of the wafer than a lateral device of the same voltage rating. More unit cells lead to increased width of the current path, and thus larger cross-sectional area, which reduces resistance in the channel. A shorter distance for current to flow and a low resistivity give rise to a lower resistance, R, than conventional high voltage devices since R=ρ L/A, where A is the cross-sectional area of the channel, or current path. In addition, GaN layers grown on bulk GaN substrates have low defect density compared to layers grown on mismatched substrates. The low defect density results in superior thermal conductivity, less trap related effects such as dynamic on-resistance, lower leakage currents, and increased reliability.

The ability to obtain regions that can support high voltage with low resistance compared to similar device structures in other materials allows embodiments of the present invention to provide resistance properties and voltage capability of conventional devices, while using significantly less area for the GaN device. Capacitance, C, scales with area, approximated as C=εA/t, so the smaller device will have less terminal-to-terminal capacitance. Lower capacitance leads to faster switching and less switching power loss. The combination of devices described herein enables the vertical diode (e.g., a Schottky diode) to take advantage of the GaN material properties in the vertical direction, independent of the lateral HEMT.

As described below, the ability to create a horizontal device in GaN grown on bulk GaN substrates will enable a smaller active area device with the same voltage handling capability and same on-state resistance as a larger device in conventional material systems due to the GaN material properties. Conversely, a device of the same size will possess lower on-state resistance with the same voltage blocking capability and capacitance. As described more fully throughout the present specification, a vertical Schottky diode can be implemented that operates in conjunction with a lateral HEMT and shares some common device layers. Some of the same advantages resulting from the material properties of the GaN-based materials can be shared by the devices. Another benefit provided by embodiments of the present invention is that an integrated HEMT and Schottky diode can reduce the number of power semiconductor components in the circuit, thereby reducing system size and cost.

These and other embodiments of the invention along with many of its advantages and features are described in more detail in conjunction with the text below and attached figures.

### BRIEF DESCRIPTION OF THE DRAWINGS

FIGS. 1A-1G are simplified process diagrams illustrating fabrication of a horizontal HEMT with a Schottky gate integrated with a Schottky diode according to an embodiment of the present invention;

FIGS. 2A-2J are simplified process diagrams illustrating fabrication of a horizontal HEMT with a p-n junction gate integrated with a Schottky diode according to an embodiment of the present invention;

FIGS. 3A-3J are simplified process diagrams illustrating fabrication of a horizontal HEMT with an MIS gate integrated with a Schottky diode according to an embodiment of the present invention;

FIG. 4A is a simplified plan view of contacts for a horizontal HEMT integrated with a Schottky diode according to an embodiment of the present invention;

FIG. 4B is a circuit diagram illustrating terminals of a horizontal HEMT integrated with a Schottky diode according to an embodiment of the present invention;

FIG. 4C is a circuit diagram illustrating terminals of a horizontal HEMT integrated with a Schottky diode according to another embodiment of the present invention;

FIG. 5 is a circuit diagram illustrating implementation of a HEMTKY in a battery charging application according to an embodiment of the present invention;

FIG. 6 is a simplified flowchart illustrated fabrication of a Schottky gated HEMT integrated with a Schottky diode according to an embodiment of the present invention;

FIG. 7 is a simplified flowchart illustrating fabrication of a p-n junction gated HEMT integrated with a Schottky diode according to an embodiment of the present invention; and

FIG. 8 is a simplified flowchart illustrated fabrication of an MIS gated HEMT integrated with a Schottky diode according to an embodiment of the present invention.

### DETAILED DESCRIPTION OF SPECIFIC EMBODIMENTS

Embodiments of the present invention relate to electronic devices. More specifically, the present invention relates to methods and systems for a HEMT monolithically integrated with a Schottky diode. Merely by way of example, the invention has been applied to integration of these structures in III-nitride based materials to provide for high power operation. The methods and techniques can be applied to a variety of compound semiconductor systems including transistors, diodes, thyristors, and others.

Some silicon devices (such as MOSFETs) contain an inherent body diode. It is not generally possible to optimize this diode separately from the transistor design, so compromises are made and normally favor the transistor design over the diode. The diode includes a p-n junction, with a high turn-on voltage compared to a Schottky diode and is thus characterized by relatively slow switching behavior due to minority carrier storage. In order to obtain both an optimized transistor and an optimized diode, the silicon MOSFET can be co-packaged with a Schottky diode, referred to as a FETKY. The Schottky diode bypasses the internal body diode with an optimized diode design in terms of voltage handling capability, switching speed, and on-state resistance. This diode is useful in many circuit applications, for example, it disallows current flow in one direction for lithium ion battery charging, it can protect (asymmetric) FET devices, and it provides a flyback function in an inductive circuit environment. In many applications, for example switching voltage inverters, the body diode is used as a freewheeling diode.

According to embodiments of the present invention, a horizontal (also referred to as a lateral) HEMT and a Schottky diode are monolithically integrated using GaN-based materials, thereby reducing packaging and assembly cost, as well as system size for higher system power density. Among other benefits, monolithic integration minimizes stray package and interconnect inductances. The availability of GaN epitaxy on pseudo bulk GaN wafers enables the creation of the vertical diode integrated with the lateral HEMT. As described below, in an embodiment, GaN epitaxy on pseudo bulk GaN wafers is used to enable the fabrication of vertically integrated devices.

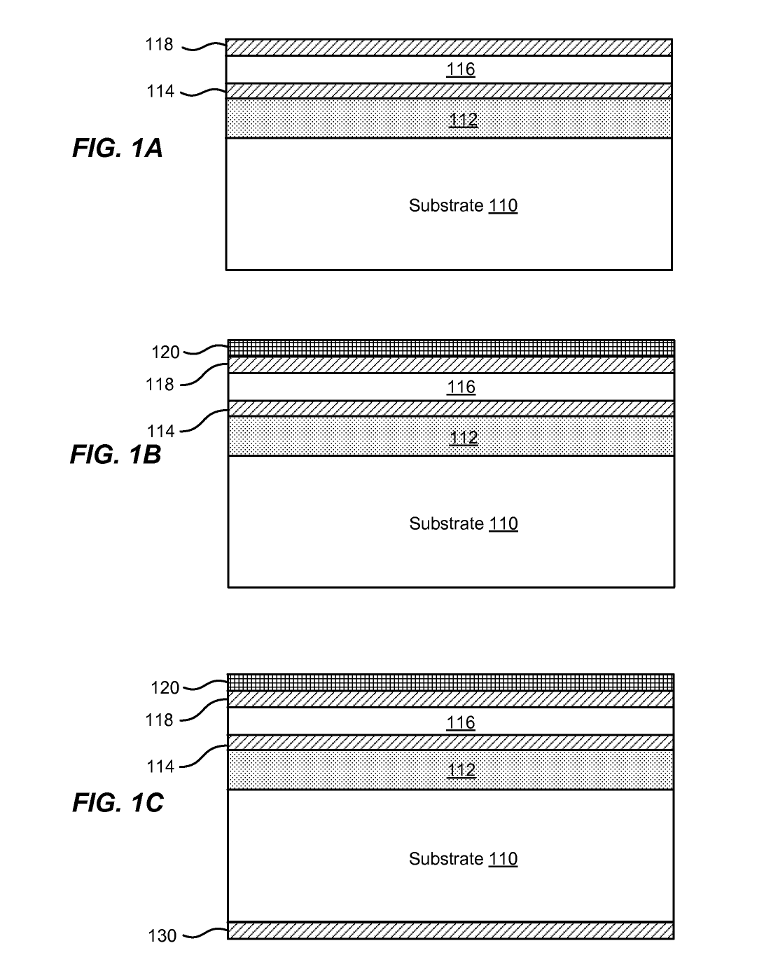

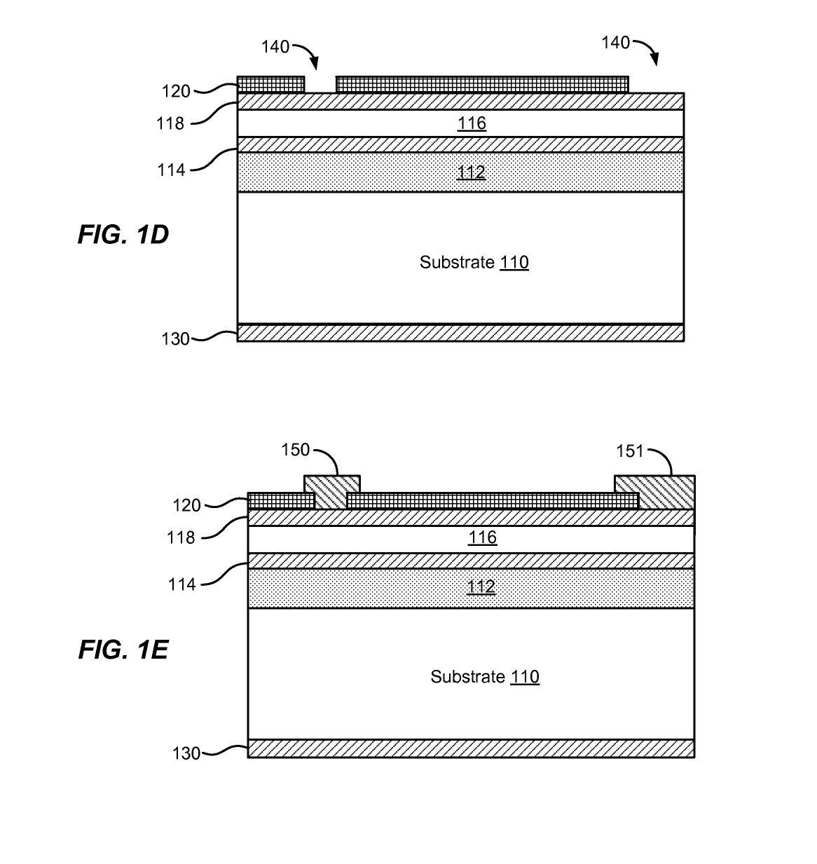

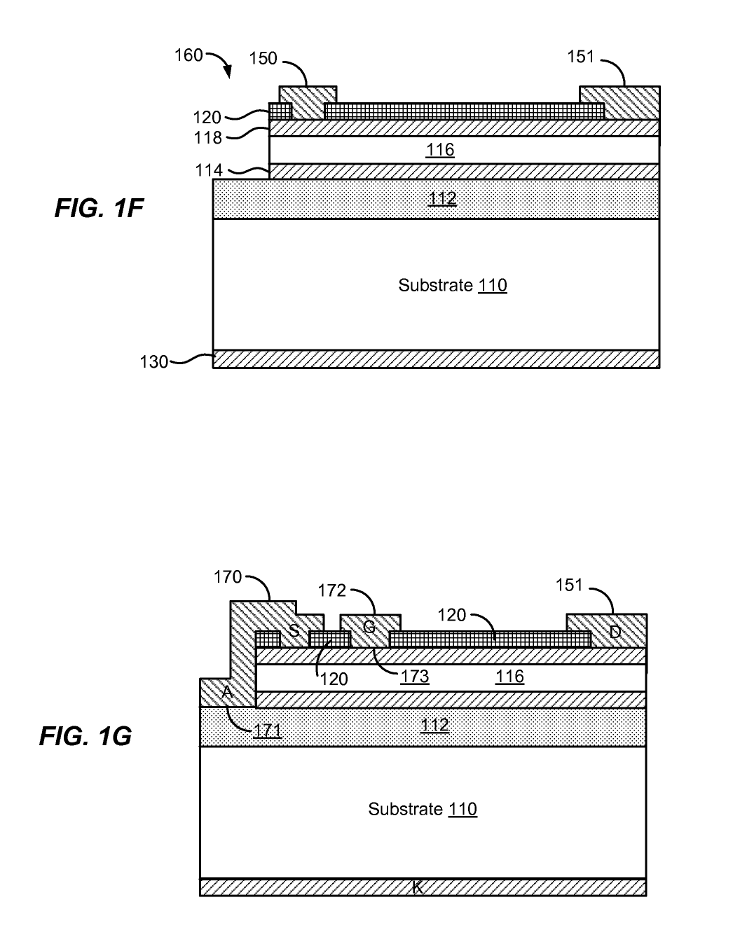

FIGS. 1A-1G are simplified process diagrams illustrating fabrication of a horizontal HEMT with a Schottky gate integrated with a Schottky diode according to an embodiment of the present invention. As illustrated in FIG. 1G, a horizontal HEMT is integrated with a GaN Schottky diode. Thus, the functionality of a three terminal transistor switch is supplemented by an optimized diode.

The fabrication process illustrated in FIGS. 1A-1G utilizes a process flow in which an n-type drift layer is grown using an n-type substrate. Referring to FIG. 1, a substrate 110 is provided. In the illustrated embodiment, the substrate 110, which will be a cathode of the Schottky diode, is an n-type GaN substrate, but the present invention is not limited to this particular material. In other embodiments, substrates with p-type doping are utilized. Additionally, although a GaN substrate is illustrated in FIG. 1A, embodiments of the present invention are not limited to GaN substrates. Other III-V materials, in particular, III-nitride materials, are included within the scope of the present invention and can be substituted not only for the illustrated GaN substrate, but also for other GaN-based layers and structures described herein. As examples, binary III-V (e.g., III-nitride) materials, ternary III-V (e.g., III-nitride) materials such as InGaN and AlGaN, quaternary III-nitride materials, such as AlInGaN, doped versions of these materials, and the like are included within the scope of the present invention. Additionally, embodiments can use materials having an opposite conductivity type to provide devices with different functionality. Other lateral transistors structures, such as MISFETs or MESFETs, could also be utilized in a similar manner as will be evident to one of skill in the art.

Although some embodiments are discussed in terms of GaN substrates and GaN epitaxial layers, the present invention is not limited to these particular binary III-V materials and is applicable to a broader class of III-V materials, in particular III-nitride materials. Thus, although some examples relate to the growth of n-type GaN epitaxial layer(s) doped with silicon, in other embodiments the techniques described herein are applicable to the growth of highly or lightly doped material, p-type material, material doped with dopants in addition to or other than silicon such as Mg, Ca, Be, Ge, Se, S, O, Te, and the like. The substrates discussed herein can include a single material system or multiple material systems including composite structures of multiple layers. One of ordinary skill in the art would recognize many variations, modifications, and alternatives.

Coupled to the substrate 110, an epitaxial layer 112 is grown, which will provide a drift region of n-type GaN material for the Schottky diode. The epitaxial layer 112 acting as the drift layer will have properties such as thickness and doping concentration that are determined by the Schottky diode design. As an example, the drift layer could have a thickness of 3.7 μm with a dopant concentration of 4.75×10¹⁶ cm⁻³ donors for a 600V breakdown diode. In typical embodiments, the thickness of epitaxial layer 112 ranges from about 1 μm to about 100 μm and the doping concentration ranges from about 1×10¹⁴ cm⁻³ to about 1×10¹⁷ cm⁻³. In other embodiments, the thickness and doping concentration are modified as appropriate to the particular application. Additional description related to thicknesses, dopant concentrations, and breakdown voltages of the drift layer are provided in U.S. patent application Ser. No. 13/198,661, filed on Aug. 4, 2011, the disclosure of which is hereby incorporated by reference in its entirety. A back barrier 114 is coupled to epitaxial layer 112 for use in isolating the lateral HEMT from the substrate 110. In an embodiment, the epitaxial layer making up the back barrier 114 is formed of AlGaN. A lightly doped GaN epitaxial layer 116 is grown as a buffer layer and an AlGaN barrier layer 118 is grown as illustrated in FIG. 1A. Epitaxial layer 116 is a lightly doped layer in the illustrated embodiment with a thickness ranging from about 0.5 μm to about 10 μm and a doping concentration in the range of about 1×10¹⁴ cm⁻³ to about 5×10¹⁶ cm⁻³. AlGaN barrier layer 118 is an unintentionally doped or intentionally n-type layer in the illustrated embodiment with a thickness ranging from about 100 Å to about 1000 Å and a doping concentration in the range of about 1×10¹⁴ cm⁻³ to about 1×10¹⁸ cm⁻³. Although an AlGaN layer is used as the larger bandgap material in the heterostructure, this is not required by the present invention and other embodiments can utilize other III-nitride materials such as InAlN, AlN, or combinations of materials as the barrier layer material. One of ordinary skill in the art would recognize many variations, modifications, and alternatives.

Referring to FIG. 1B, a surface passivating insulator layer 120 is deposited, for example, an oxide or nitride layer such as SiOₓ or SiNₓ. An electrical contact 130 to the substrate 110 is formed as illustrated in FIG. 1C.

A masking and material removal process (e.g., etching) is used to form open regions 140, which will provide contact to AlGaN barrier layer 118 for the source and drain ohmic contacts. Suitable source and drain ohmic metal contacts 150 and 151 can be deposited and patterned as illustrated in FIG. 1E. In some embodiments, ohmic metals for contacts 130, 150, and 151 are deposited and annealed as part of a combined process. Electrical contacts 130, 150, and 151 can be deposited and annealed prior to the subsequent deposition of Schottky contacts, which are not typically capable of surviving the ohmic contact anneal temperatures, typically >800° C. for >3 minutes.

In order to form the Schottky diode, the epitaxial layers in the desired location are removed (e.g., using an etching process) in region 160 to expose epitaxial layer 112, which is the drift layer for the Schottky diode. In the embodiment illustrated in FIG. 1F, the material removal process terminates at the interface between epitaxial layers 112 and 114, but in other embodiments, the material removal process can terminate at other depths in the structure. One of ordinary skill in the art would recognize many variations, modifications, and alternatives. Additionally, an additional opening in insulating layer 120 is made as illustrated in FIG. 1G to enable electrical contact between Schottky metal 172 and the AlGaN barrier layer 118. Referring to FIG. 1G, the exposed surfaces 171 and 173 are treated to place them in a condition suitable for a Schottky barrier and Schottky metals 170 and 172 are deposited and patterned using a suitable electrically conductive material. Examples of Schottky metals include nickel, palladium, platinum, combinations thereof, or the like. The geometry of the Schottky contacts 170 and 172 will be a function of the device geometry for the Schottky diode and the horizontal HEMT. As illustrated in FIG. 1G, in some embodiments, Schottky metal 170 can make physical contact with the HEMT's source ohmic metal 150 (illustrated in FIG. 1F), or it could be connected by another means later, such as another metal interconnect layer or wirebond(s). As will be evident to one of skill in the art, Schottky metal 172 serves as the gate of the lateral HEMT and can be deposited and patterned in the same process as Schottky metal 170. The source (S), drain (D), and gate (G) of the HEMT and the anode (A) and cathode (K) of the Schottky diode are illustrated in FIG. 1G. The contacts 150, 172, 151, 130, and 170 can be formed from one or more layers of electrical conductors including a variety of metals to electrically couple the horizontal HEMT and the Schottky diode to an electrical circuit (not illustrated).

Other variations of the HEMT illustrated in FIG. 1G can be implemented including the use of a GaN cap, an AlN channel confinement layer, or a double heterostructure, among others. One of ordinary skill in the art would recognize many variations, modifications, and alternatives.

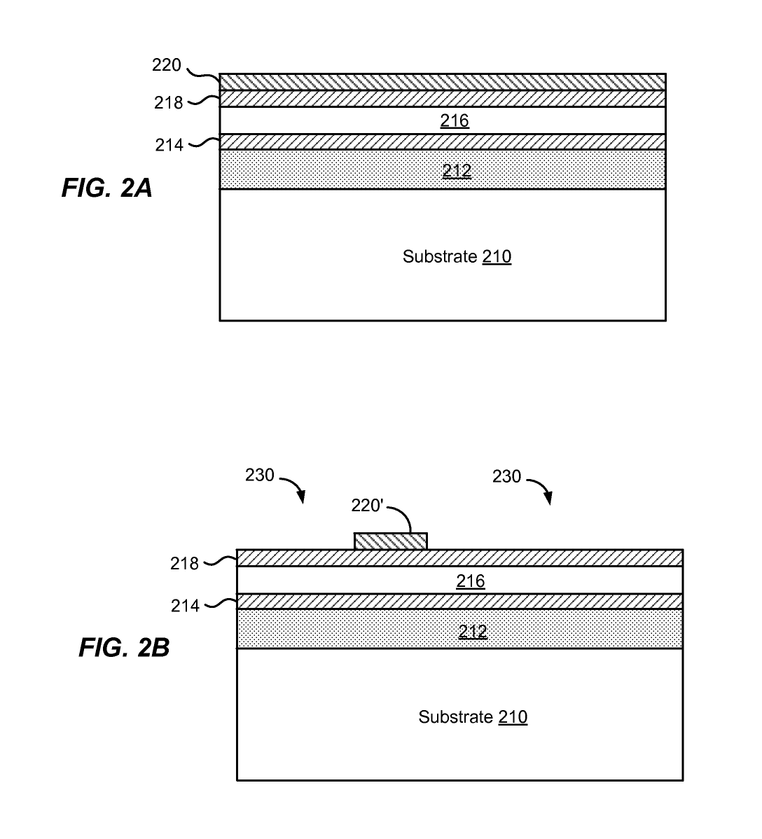

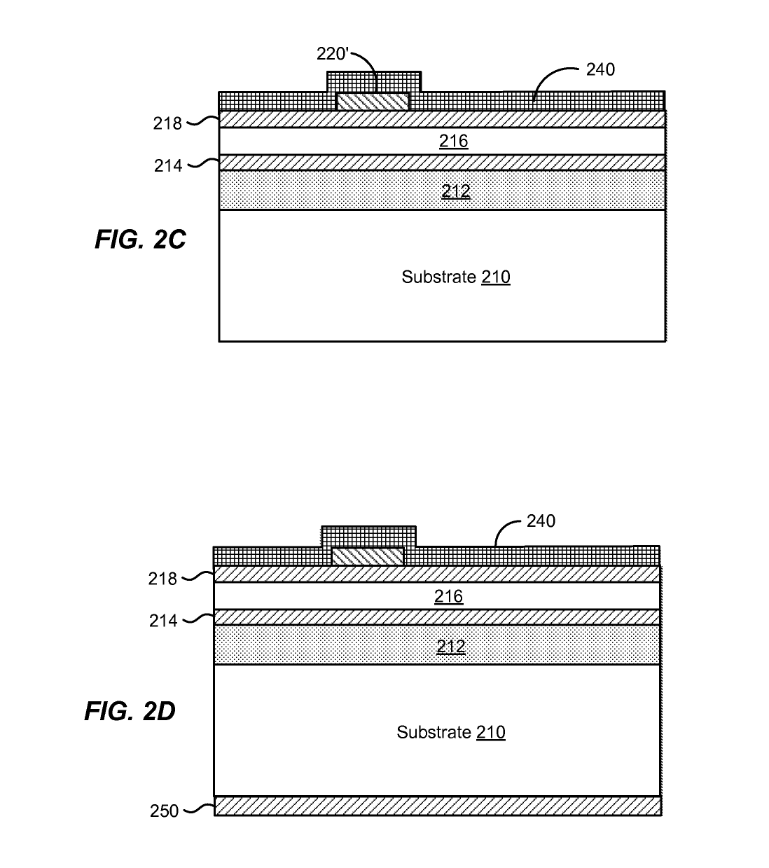

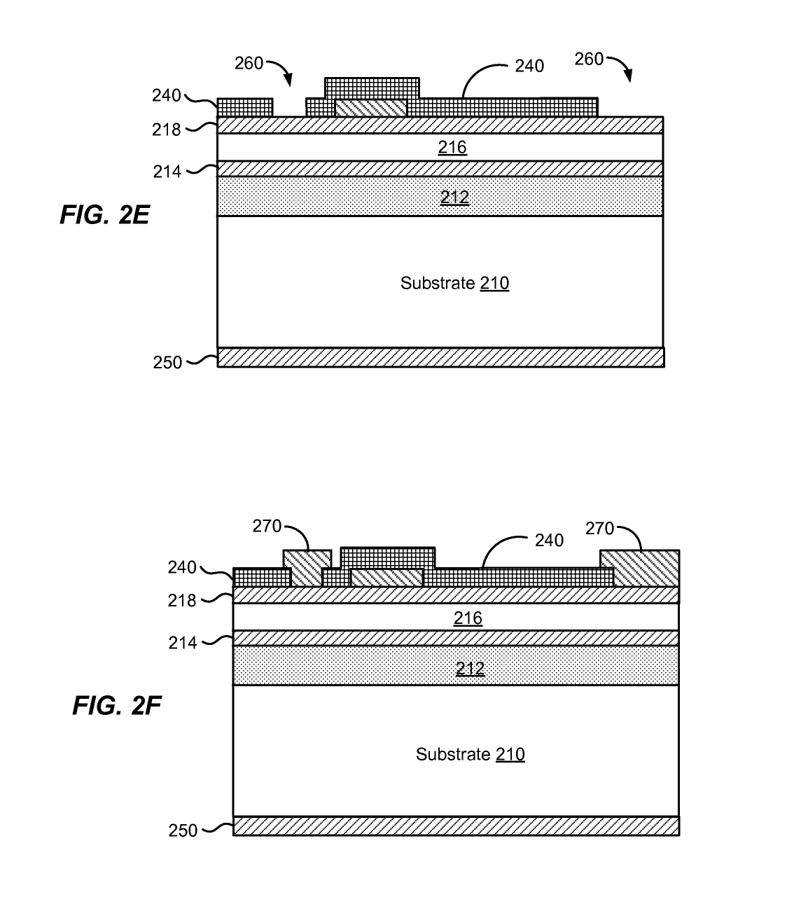

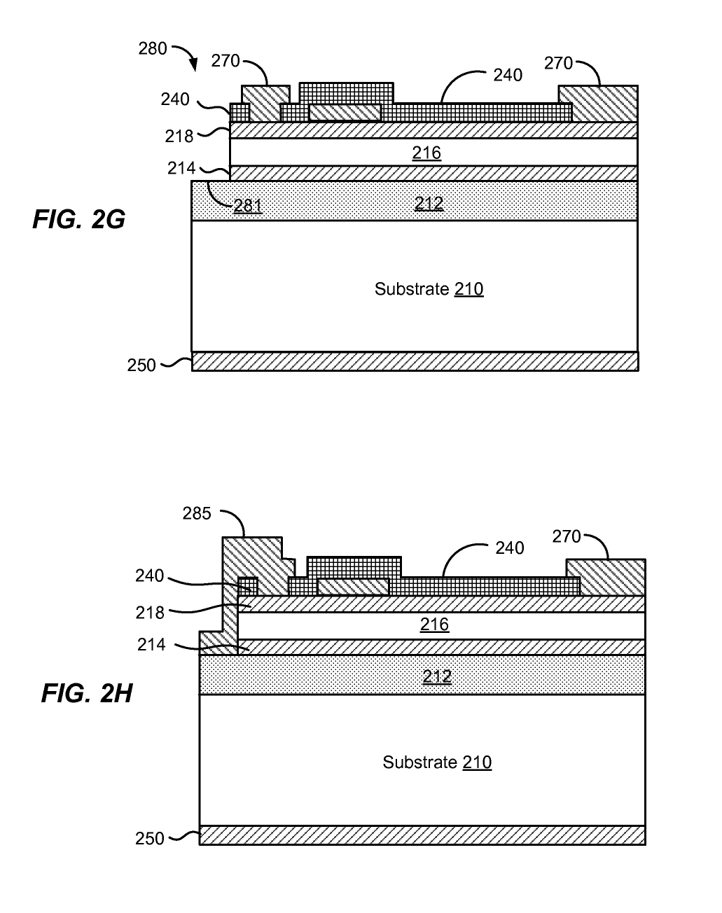

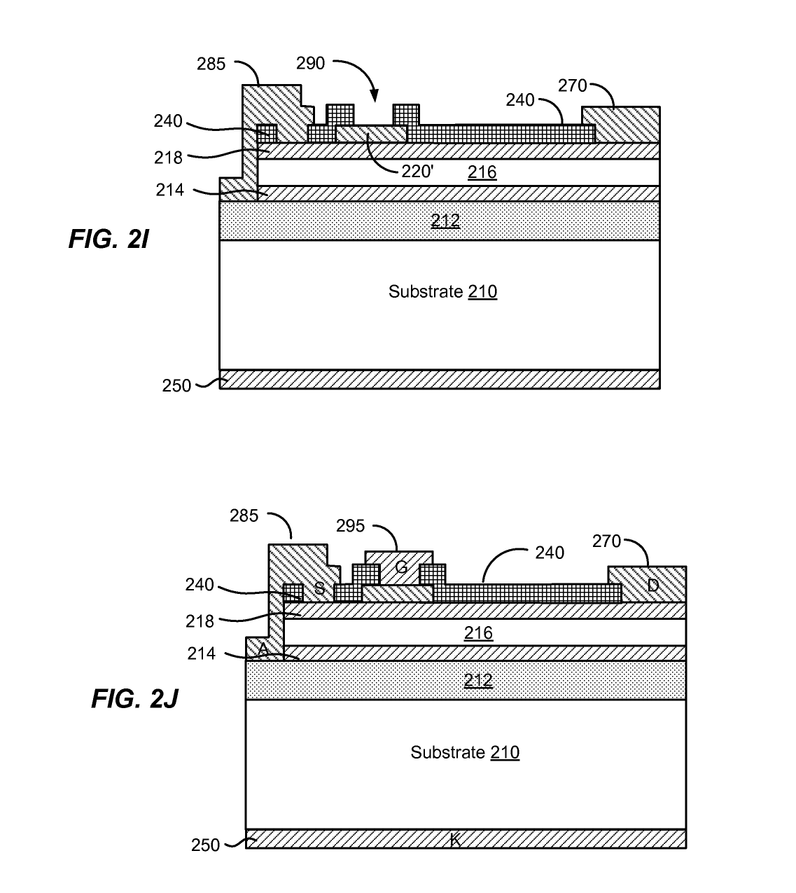

FIGS. 2A-2J are simplified process diagrams illustrating fabrication of a horizontal HEMT with a p-n junction gate integrated with a Schottky diode according to an embodiment of the present invention. The process flow illustrated in FIGS. 2A-2J shares some similarities with the process flow illustrated in FIGS. 1A-G, and, therefore, some redundant description is omitted for purposes of brevity. Although there are similarities, the HEMT with a p-n junction gate described in FIGS. 2A-2J does feature several differences in design.

Referring to FIG. 2A, a substrate 210, which will serve as cathode of the Schottky diode, an epitaxial layer 212, which will provide a drift region of n-type GaN material for the Schottky diode, a back barrier 214 coupled to epitaxial layer 212 for use in isolating the lateral HEMT from the substrate 210, a lightly doped GaN epitaxial layer 216 that serves as a buffer layer, and an AlGaN barrier layer 218 are illustrated. As discussed in relation to FIG. 1A, the various epitaxial layers illustrated in FIG. 2A are provided as examples and are not intended to limit embodiments of the present invention to the particular exemplary materials.

A p+ AlGaN epitaxial layer 220 is grown on the epitaxial stack as illustrated in FIG. 2A in order to provide a p-type material for the p-n junction gated HEMT described below. In embodiments in which a p-type substrate is utilized, epitaxial layer 220 can be an n-type layer as appropriate to the underlying epitaxial structure. Referring to FIG. 2B, portions 230 of epitaxial layer 220 are removed (e.g., using a photolithographic patterning/masking and etching process) to form the gate region 220′. In some embodiments, the ohmic gate metal 295, described in relation to FIG. 2J below, is deposited and patterned along with epitaxial layer 220, resulting in an ohmic metal connected to the gate region 220′ illustrated in FIG. 2B. A blanket deposition of an insulating material 240 (which may also have passivating properties) such as silicon nitride, silicon oxide, or the like, is illustrated in FIG. 2C.

An ohmic metal layer 250 is deposited on the backside of the substrate 210 as shown in FIG. 2D to provide an ohmic contact for the cathode of the Schottky diode. As illustrated in FIG. 2E, regions 260 of insulating layer 240 are removed, for example, using an etching process, to expose portions of the epitaxial layer 218 suitable for formation of the source and drain of the HEMT. In some embodiments, an etching process is utilized that terminates at the interface between the AlGaN layer and the overlying insulator, whereas in other embodiments, the etch extends to a given distance into the AlGaN epitaxial layer 218.

Ohmic metals 270 are deposited and patterned (FIG. 2F) to provide for electrical contact to the source and drain of the HEMT. As discussed in relation to FIG. 1E, an anneal process for ohmic metals 250 and 270 can be performed, for example, at a temperature >800° C. for >3 minutes.

Referring to FIG. 2G, region 280 is removed using an etching or other suitable removal process to provide a Schottky contact region for the anode of the Schottky diode. As illustrated in FIG. 2G, the removal process extends to epitaxial layer 212 in a manner similar to the removal process illustrated in FIG. 1F. Referring to FIGS. 2G and 2H, the exposed surface 281 is treated to place it in a condition suitable for a Schottky barrier and Schottky metal 285 is deposited and patterned using a suitable electrically conductive material. Examples of Schottky metals include nickel, palladium, platinum, combinations thereof, of the like. The geometry of the Schottky contact 285 will be a function of the device geometry for the Schottky diode and the horizontal HEMT. As illustrated in FIG. 2H, in some embodiments, Schottky metal 285 can make physical contact with the HEMT's source ohmic metal 270 (illustrated in FIG. 2G), or it could be connected by another means later, such as another metal interconnect layer or wirebond(s).

A masking and etching process, or other suitable removal process, is used to open region 290 passing through insulating layer 240 above gate region 220′ (FIG. 21). Ohmic gate metal 295 is deposited and patterned to provide an electrical connection to the gate of the HEMT. The source (S), drain (D), and gate (G) of the HEMT and the anode (A) and cathode (K) of the Schottky diode are illustrated in FIG. 2J. As discussed in relation to FIG. 1G, the various ohmic and Schottky contacts can be formed from one or more layers of electrical conductors including a variety of metals to electrically couple the horizontal HEMT and the Schottky diode to an electrical circuit (not illustrated). Thus, as illustrated in FIG. 2J, a p-n junction gated HEMT integrated with a Schottky diode is provided by some embodiments of the present invention.

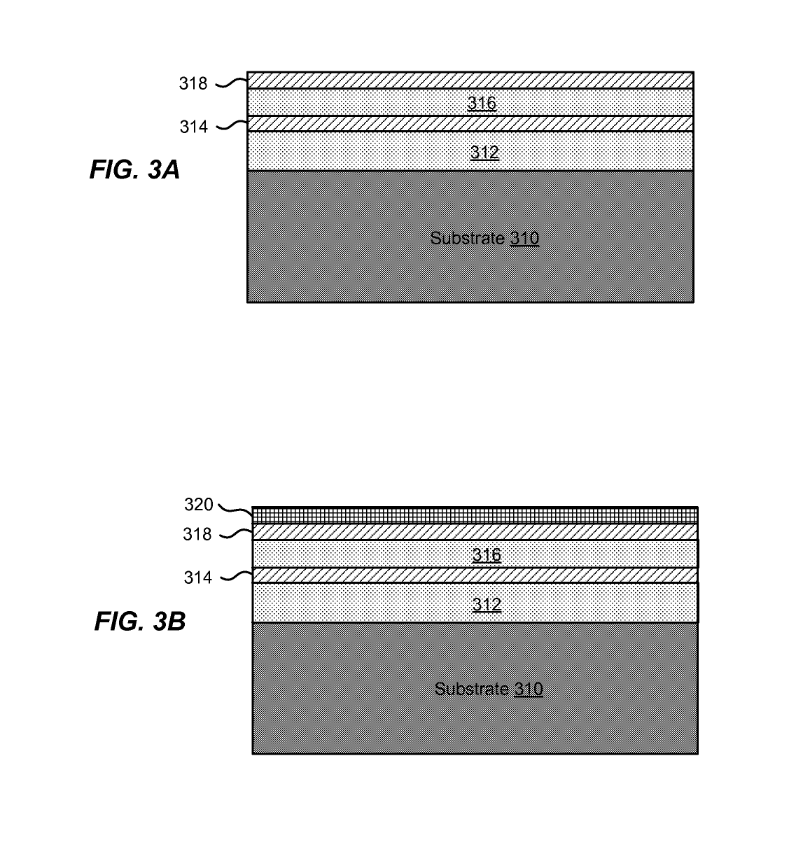

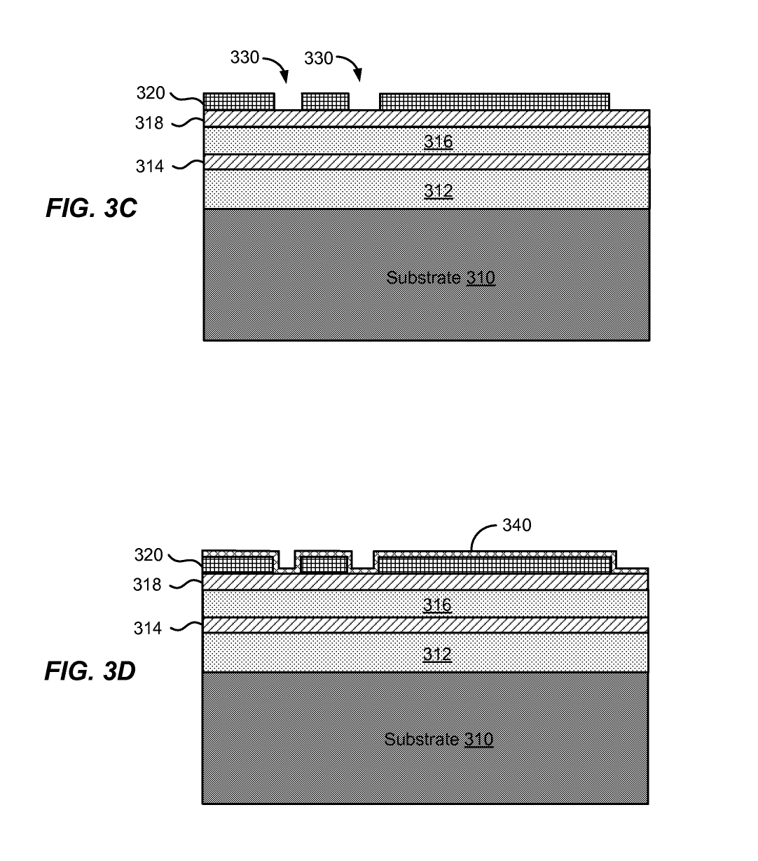

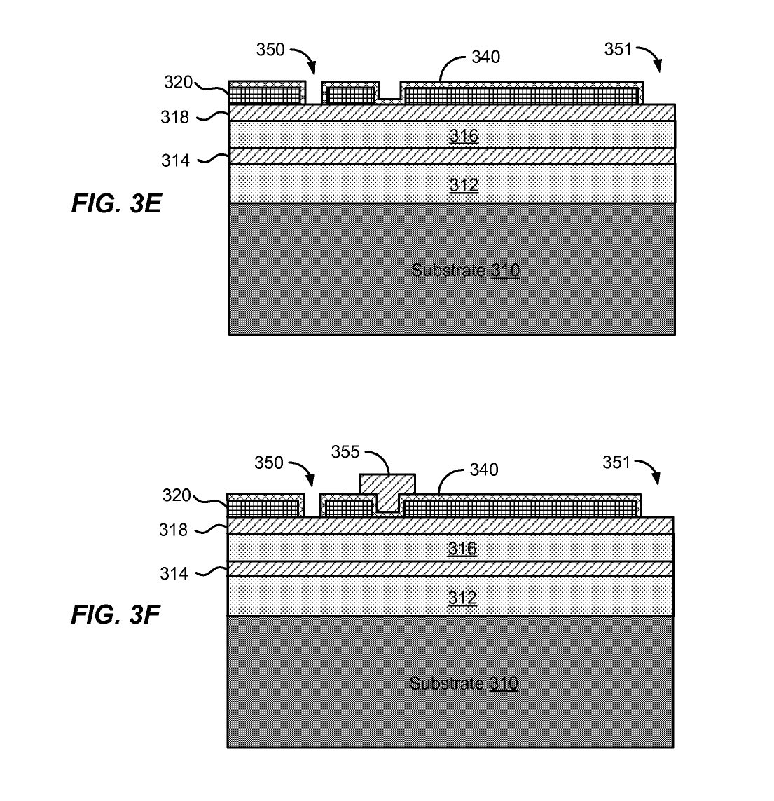

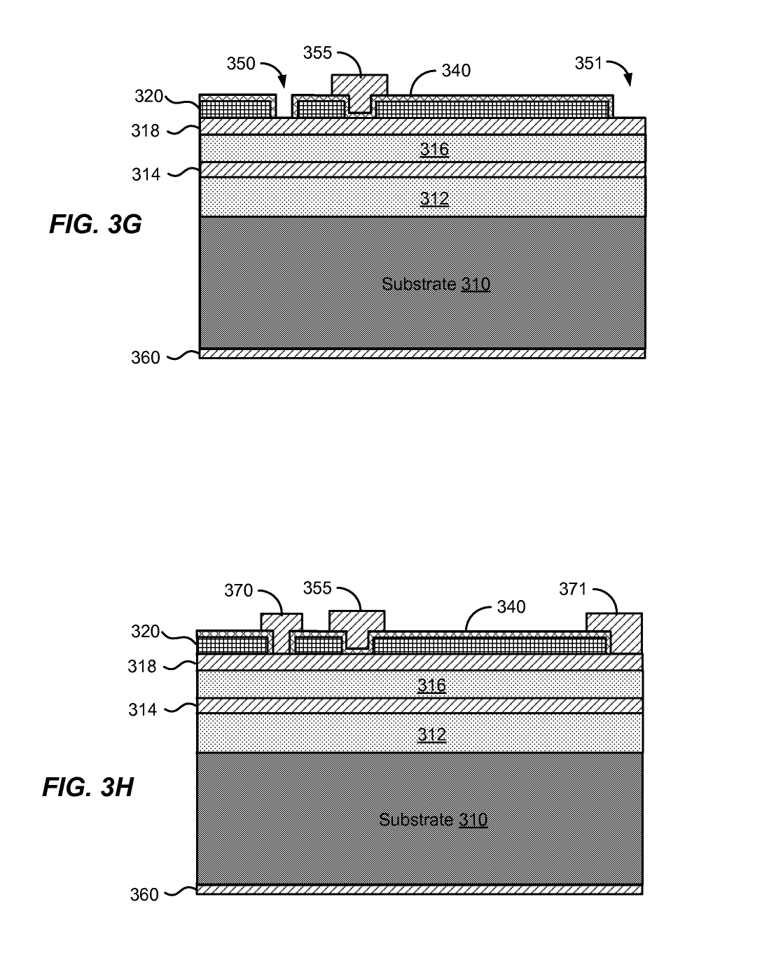

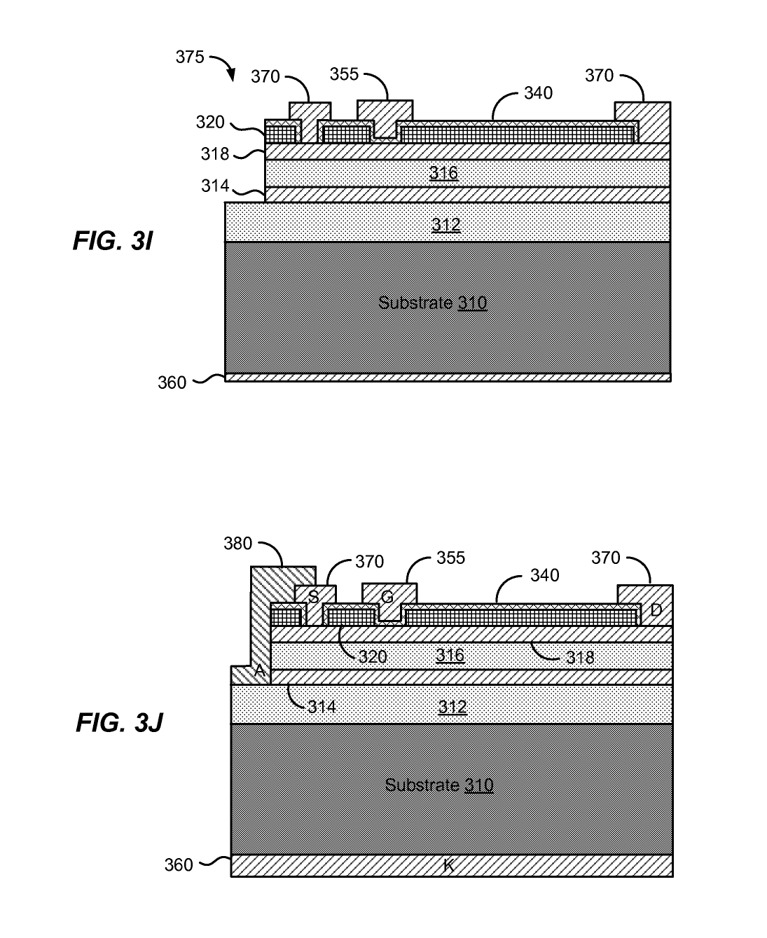

FIGS. 3A-3J are simplified process diagrams illustrating fabrication of a horizontal HEMT with an MIS gate integrated with a Schottky diode according to an embodiment of the present invention. The process flow illustrated in FIGS. 3A-2J shares some similarities with the process flows illustrated in FIGS. 1A-G and 2A-2J, and, therefore, some redundant description is omitted for purposes of brevity. Although there are similarities, the MIS gated HEMT described in FIGS. 3A-3J does feature several differences in design.

Referring to FIG. 3A, a substrate 310 (n+-GaN), epitaxial layer 312 (n− GaN drift layer), epitaxial layer 314 (AlGaN back barrier), epitaxial layer 316 (n− GaN), and epitaxial layer 318 (AlGaN) are illustrated. An insulating/passivating layer 320 (FIG. 3B) is deposited and openings 330 are made (FIG. 3C) to define the gate region and expose epitaxial layer 318 for the drain of the lateral HEMT. A gate dielectric 340, which can be a silicon nitride, silicon oxide, or other suitable insulating layer is deposited in FIG. 3D. The gate dielectric is illustrated as unpatterned in FIG. 3D although this is not required by embodiments of the present invention.

Source region 350 and drain region 351 are opened through the gate dielectric as shown in FIG. 3E using, for example, an etching process. The surfaces of epitaxial layer 318 are thus exposed for use in making ohmic contact to these regions. A gate metal 355 is deposited and patterned (FIG. 3F) and an ohmic contact layer 360 is formed in electrical contact with substrate 310 (FIG. 3G). Referring to FIG. 3H, suitable source ohmic metal 370 and drain ohmic metal 371 are deposited and patterned. An ohmic anneal is performed for the ohmic metals, typically >800° C. for >3 minutes.

In order to form the Schottky diode, epitaxial layers in region 375 are removed (FIG. 3I) in the desired location, for example, by etching down to the drift layer. Following etching, the exposed surface is treated to make it suitable for a Schottky barrier, and then Schottky metal 380 is deposited and patterned (FIG. 3J). The Schottky metal could physically contact the HEMT's source ohmic metal, or it could be connected by another means later, such as another metal interconnect layer or wirebond. The source (S), drain (D), and gate (G) of the HEMT and the anode (A) and cathode (K) of the Schottky diode are illustrated in FIG. 3J. Thus, as illustrated in FIG. 3J, the gate dielectric 340 present between the gate metal 355 and epitaxial layer 318 results in an MIS gated HEMT integrated with a Schottky diode in this embodiment of the present invention.

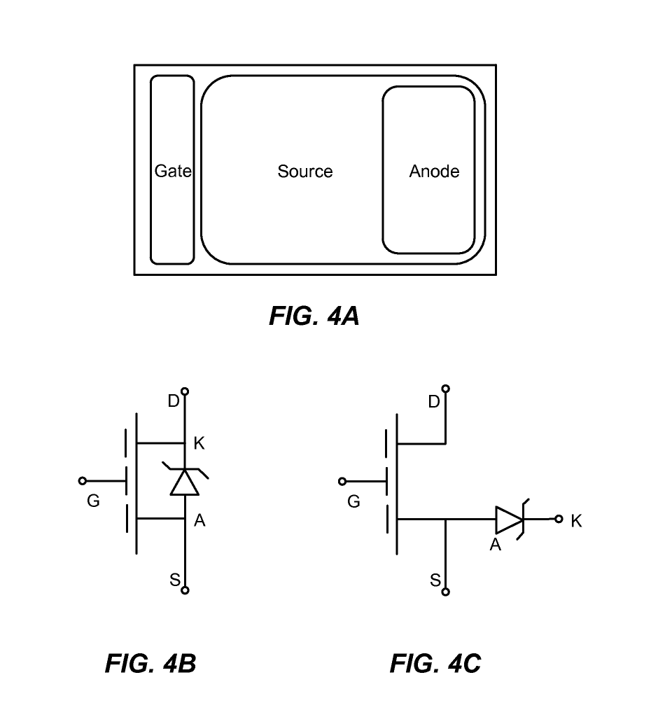

Various alternatives exist for the monolithic integration of the horizontal HEMT and the vertical Schottky diode. In one configuration, the horizontal HEMT occupies an area unto itself and the Schottky diode is fabricated adjacent to the horizontal HEMT. Interconnections can be made by wirebond or by on-chip metallization. FIG. 4A is a simplified plan view of contacts for a horizontal HEMT integrated with a Schottky diode according to an embodiment of the present invention. Another possible embodiment is for each unit cell of the device to contain fingers of the horizontal HEMT and Schottky devices. In this way, the two devices are intermeshed resulting in significant space savings. In both configurations, the overall size of the device can be scaled for the desired current handling capability. FIG. 4B is a circuit diagram illustrating terminals of a horizontal HEMT integrated with a Schottky diode according to an embodiment of the present invention. As illustrated in FIG. 4B, the cathode (K) and the drain (D) are connected to a same terminal and the anode (A) and the source (S) are also connected to a same terminal. FIG. 4C is a circuit diagram illustrating terminals of a horizontal HEMT integrated with a Schottky diode according to another embodiment of the present invention. As illustrated in FIG. 4C, the anode (A) and the source (S) are connected to a same terminal while the cathode (K) is electrically separated from the drain (D). One of ordinary skill in the art would recognize many variations, modifications, and alternatives. The various HEMT designs with a Schottky gate, a p-n junction gate, or an MIS gate can be utilized in the circuit diagrams illustrated herein as well as other suitable circuits.

In alternative embodiments, other device configurations are utilized including side-by-side monolithic integration of the HEMT and the vertical Schottky diode. In a particular construction, the HEMT occupies an area unto itself, and the Schottky diode is fabricated beside it. Interconnections can be made by wirebond or by on-chip metallization. Another possibility is for each unit cell of the device to contain interleaved fingers of the HEMT and Schottky devices. In this way, the two devices share the same area, resulting in drastic space savings. In both configurations the overall size of the device can be scaled for the desired current handling capability. In either of these configurations, most possible variations of the non-integrated HEMT design that have been demonstrated can also be implemented, for example devices with source and/or gate field plates.

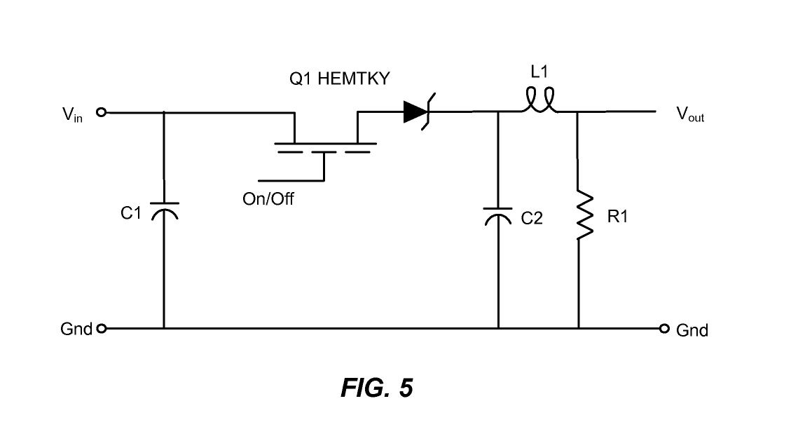

FIG. 5 is a circuit diagram illustrating implementation of a HEMT monolithically integrated with a Schottky diode (“HEMTKY”) in a battery charging application according to an embodiment of the present invention. A voltage input (Vᵢₙ) is applied across a capacitor (C1) and applied to a drain of Q1, which is a HEMTKY in the illustrated embodiment. In the illustrated circuit, the HEMTKY Q1 is wired so that the anode of the Schottky diode is electrically connected to the source of the HEMT. The cathode of the Schottky diode is electrically connected to a second capacitor (C2) and inductor (L1). Voltage output (Vₒᵤₜ) is produced across resistor R1. The circuit implementation illustrated in FIG. 5 is merely exemplary and many benefits are provided by embodiments of the present invention including reduced component cost, smaller device packages, and the like.

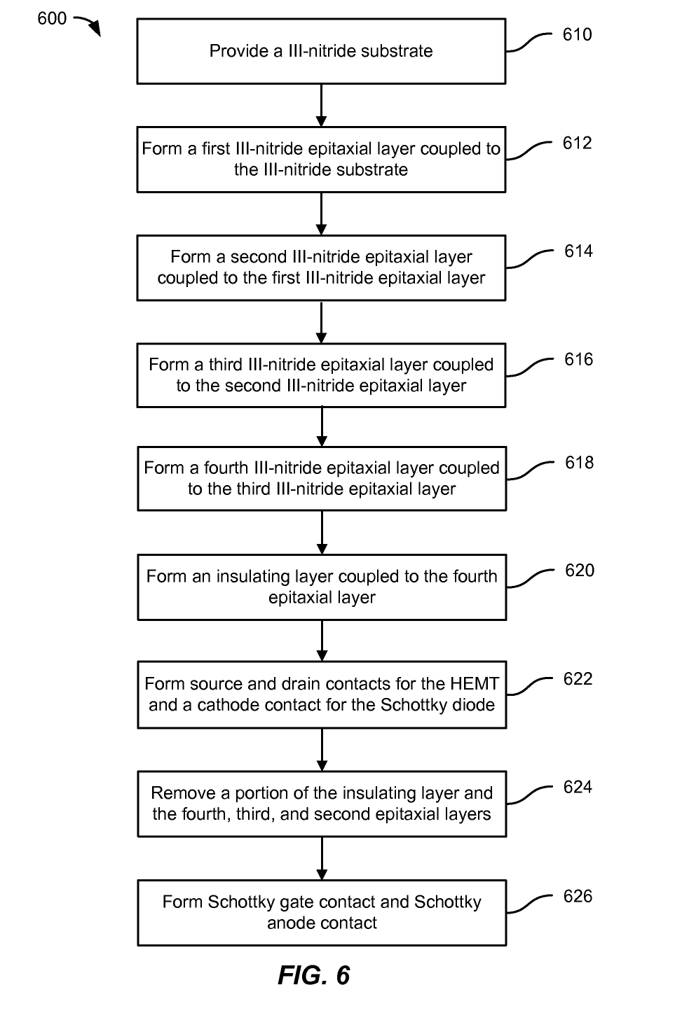

FIG. 6 is a simplified flowchart illustrated fabrication of a Schottky gated HEMT integrated with a Schottky diode according to an embodiment of the present invention. The method 600 includes providing a III-nitride substrate (610), which may be an n-type GaN substrate. The method also includes forming a first III-nitride epitaxial layer coupled to the III-nitride substrate (612), forming a second III-nitride epitaxial layer coupled to the first III-nitride epitaxial layer (614), forming a third III-nitride epitaxial layer coupled to the second III-nitride epitaxial layer (616), and forming a fourth III-nitride epitaxial layer coupled to the third III-nitride epitaxial layer (618). In the embodiment illustrated in FIG. 1A, the first epitaxial layer is an n- doped GaN drift layer, the second epitaxial layer is a AlGaN back barrier, the third epitaxial layer is an n- doped GaN layer, and the fourth epitaxial layer is an AlGaN layer. Using the homoepitaxy techniques described herein, the thickness of the first III-nitride epitaxial layer can be thicker than available using conventional techniques, for example, between about 1 μm and about 100 μm, more particularly, between about 3 μm and 50 μm. The various epitaxial layers do not have to be uniform in dopant concentration as a function of thickness, but may utilize varying doping profiles as appropriate to the particular application. Other layers with varying constituents, dopants, and the like are included within the scope of the present invention.

The method also includes forming an insulating layer coupled to the fourth epitaxial layer (620) and forming source and drain contacts for the HEMT and a cathode contact for the

Schottky diode (622). Formation of the source and drain contacts, also referred to as metallic structures, using ohmic metals includes removing a portion of the insulating layer to expose predetermined portions of the fourth epitaxial layer. The ohmic metals can undergo a high temperature annealing process as described above.

The method further includes removing a portion of the insulating layer, the fourth epitaxial layer, the third epitaxial layer, and the second epitaxial layer to expose a portion of the first epitaxial layer (624) as illustrated in FIG. 1F. The removal process can include a masking and etching process that can include physical etching components as well as chemical etching components. The access to the first epitaxial layer provides a location for the formation of a Schottky contact to the first epitaxial layer (i.e., the anode). Another portion of the insulating is removed to expose a portion of the fourth epitaxial layer and enable the formation of a gate contact using a Schottky metal to produce a Schottky gated HEMT.

It should be appreciated that the specific steps illustrated in FIG. 6 provide a particular method of fabricating a Schottky gated HEMT integrated with a Schottky diode according to an embodiment of the present invention. Other sequences of steps may also be performed according to alternative embodiments. For example, alternative embodiments of the present invention may perform the steps outlined above in a different order. Moreover, the individual steps illustrated in FIG. 6 may include multiple sub-steps that may be performed in various sequences as appropriate to the individual step. Furthermore, additional steps may be added or removed depending on the particular applications. One of ordinary skill in the art would recognize many variations, modifications, and alternatives.

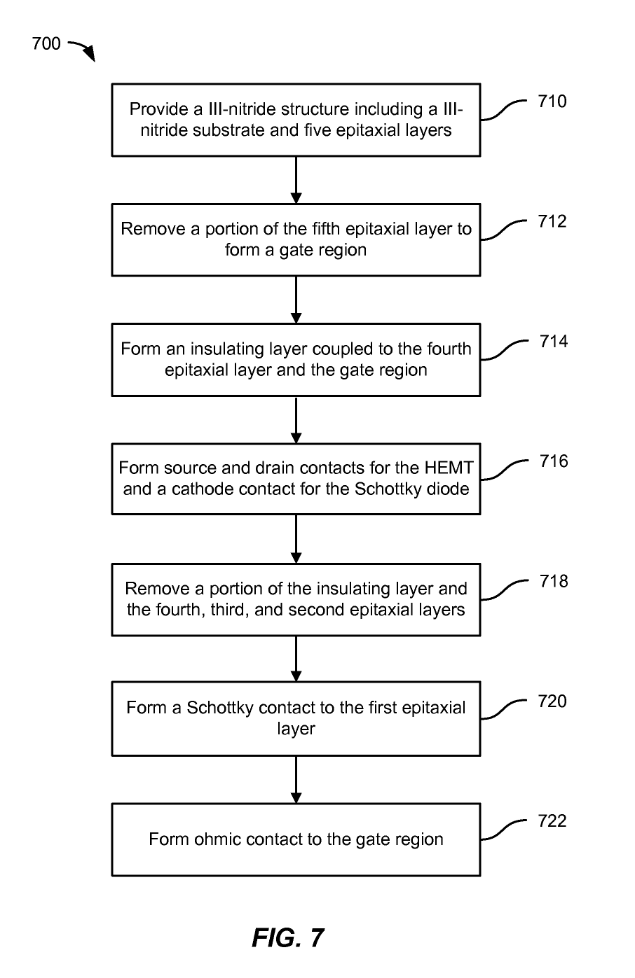

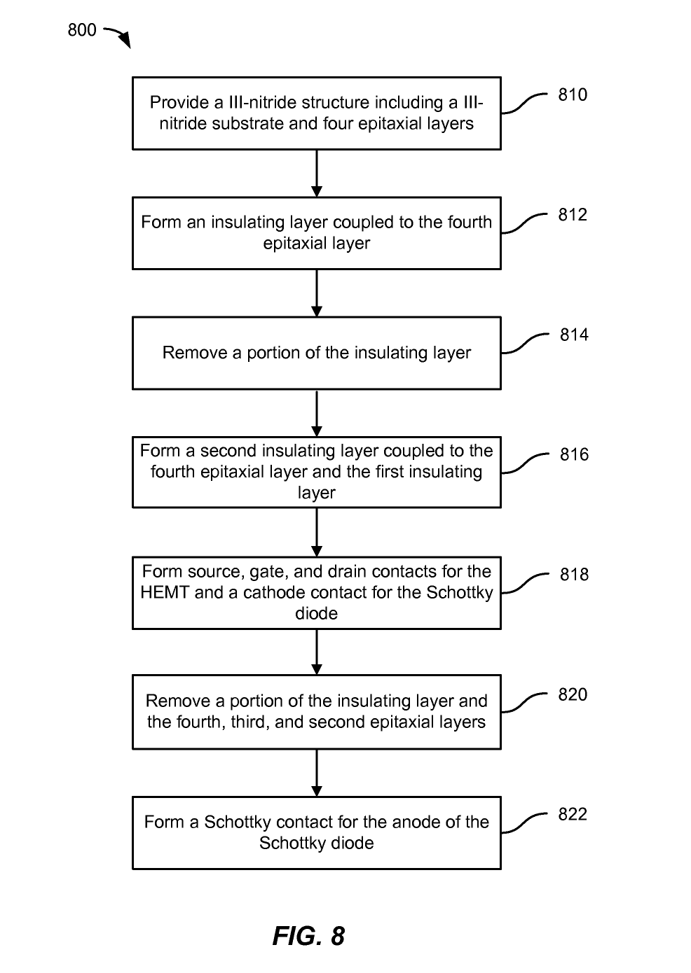

FIG. 7 is a simplified flowchart illustrating fabrication of a p-n junction gated HEMT integrated with a Schottky diode according to an embodiment of the present invention. The method 700 shares some common steps with method 600 and some redundant description is omitted for purposes of brevity.

The method 700 includes provide a III-nitride structure including a III-nitride substrate and five epitaxial layers (710). Referring to FIG. 2A, an n-type GaN substrate supports the four epitaxial layers discussed in relation to steps 612-618 of FIG. 6. Additionally, a p-type AlGaN epitaxial layer is formed for use in forming a p-n junction gate of the HEMT. A portion of the fifth epitaxial layer is removed to form a gate region (712). An insulating layer is deposited or otherwise formed such that it is coupled to the fourth epitaxial layer and the gate region (714). As illustrated in FIG. 2C, the insulating layer can be blanket deposited on the fourth epitaxial layer and the gate region, being in contact with portions of the fourth epitaxial layer in which the gate region does not overlie the fourth epitaxial layer.

The method further includes forming source and drain contacts for the HEMT and a cathode contact for the Schottky diode (716). Formation of the source and drain contacts, also referred to as metallic structures, using ohmic metals includes removing a portion of the insulating layer to expose predetermined portions of the fourth epitaxial layer. The ohmic metals can undergo a high temperature annealing process as described above.

The method further includes removing a portion of the insulating layer, the fourth epitaxial layer, the third epitaxial layer, and the second epitaxial layer to expose a portion of the first epitaxial layer (718) as illustrated in FIG. 2G. The removal process can include a masking and etching process that can include physical etching components as well as chemical etching components. The access to the first epitaxial layer provides a location for the formation of a Schottky contact to the first epitaxial layer (i.e., the anode in contact with the drift layer) (720). Additionally, the method includes forming an ohmic contact to the gate region (722). In some embodiments, the ohmic contact to the gate region can be formed at an earlier stage of the fabrication process, for example, during formation of the source and drain contacts.

It should be appreciated that the specific steps illustrated in FIG. 7 provide a particular method of fabricating a p-n junction gated HEMT integrated with a Schottky diode according to an embodiment of the present invention. Other sequences of steps may also be performed according to alternative embodiments. For example, alternative embodiments of the present invention may perform the steps outlined above in a different order. Moreover, the individual steps illustrated in FIG. 7 may include multiple sub-steps that may be performed in various sequences as appropriate to the individual step. Furthermore, additional steps may be added or removed depending on the particular applications. One of ordinary skill in the art would recognize many variations, modifications, and alternatives.

FIG. 8 is a simplified flowchart illustrated fabrication of an MIS gated HEMT integrated with a Schottky diode according to an embodiment of the present invention. The method 800 shares some common steps with methods 600 and 700 and some redundant description is omitted for purposes of brevity. The method 800 includes providing a III-nitride structure including a III-nitride substrate and four epitaxial layers (810). Referring to FIG. 3A, an n-type GaN substrate supports the four epitaxial layers discussed in relation to steps 612-618 of FIG. 6. An insulating/passivating layer is deposited or otherwise formed such that it is coupled to the fourth epitaxial layer (812). As illustrated in FIG. 3B, the insulating layer can be blanket deposited on the fourth epitaxial layer in some embodiments.

The method further includes removing a portion of the insulating layer (814) and forming a second insulating layer (816) that will be used as a gate insulator for the MIS gated HEMT. In some embodiments, a single insulating layer is used, with varying thickness or materials to provide a dielectric constant that varies as a function of position as appropriate to the device features. In other embodiments, multiple insulating layers are utilized. The source, gate, and drain contacts for the HEMT and the cathode contact for the Schottky diode are formed (818). Forming the source and drain contacts for the HEMT can include removing the second insulator to expose predetermined portions of the fourth epitaxial layer so that the source and drain can make electrical contact to the fourth epitaxial layer. A gate metal is formed, for example, using deposition and patterning, with the second insulator disposed between the gate metal and the fourth epitaxial layer. The ohmic contact for the cathode of the Schottky diode is formed, for example, using a blanket deposition. The ohmic metals can undergo a high temperature annealing process as described above.

The method further includes removing a portion of the insulating layer, the fourth epitaxial layer, the third epitaxial layer, and the second epitaxial layer to expose a portion of the first epitaxial layer (820) as illustrated in FIG. 31. The removal process can include a masking and etching process that can include physical etching components as well as chemical etching components. The access to the first epitaxial layer provides a location for the formation of a Schottky contact to the first epitaxial layer (i.e., the anode in contact with the drift layer) (822).

It should be appreciated that the specific steps illustrated in FIG. 8 provide a particular method of fabricating an MIS gated HEMT integrated with a Schottky diode according to an embodiment of the present invention. Other sequences of steps may also be performed according to alternative embodiments. For example, alternative embodiments of the present invention may perform the steps outlined above in a different order. Moreover, the individual steps illustrated in FIG. 8 may include multiple sub-steps that may be performed in various sequences as appropriate to the individual step. Furthermore, additional steps may be added or removed depending on the particular applications. One of ordinary skill in the art would recognize many variations, modifications, and alternatives.

It is also understood that the examples and embodiments described herein are for illustrative purposes only and that various modifications or changes in light thereof will be suggested to persons skilled in the art and are to be included within the spirit and purview of this application and scope of the appended claims.

What is claimed is:

1. An integrated device including a III-nitride HEMT and a Schottky diode, the integrated device comprising:
a substrate comprising a first III-nitride material;
a drift region comprising a second III-nitride material coupled to the substrate and disposed adjacent to the substrate along a vertical direction;
a first barrier layer coupled to the drift region;
a channel layer comprising a third III-nitride material having a first bandgap and coupled to the barrier layer;
a second barrier layer characterized by a second bandgap and coupled to the channel layer, wherein the second bandgap is greater than the first bandgap; and
a Schottky contact coupled to the drift region.

2. The integrated device of claim 1 further comprising:
an ohmic source contact electrically coupled to the second barrier layer;
a Schottky gate contact electrically coupled to the second barrier layer; and
an ohmic drain contact electrically coupled to the second barrier layer.

3. The integrated device of claim 2 wherein the ohmic source contact and the ohmic drain contact are separated along a horizontal direction.

4. The integrated device of claim 1 wherein the first III-nitride material comprises an n-type GaN substrate.

5. The integrated device of claim 1 wherein the second III-nitride material and the third III-nitride material comprise n-type GaN.

6. The integrated device of claim 5 wherein the second barrier layer comprises AlGaN.

7. The integrated device of claim 1 wherein the drift region has a thickness between 1 μm and 100 μm.

8. An integrated device including a III-nitride HEMT and a Schottky diode, the integrated device comprising:
a substrate comprising a first III-nitride material;
a drift region comprising a second III-nitride material coupled to the substrate and disposed adjacent to the substrate along a vertical direction;
a Schottky contact coupled to the drift region;
a first barrier layer coupled to the drift region;
a channel layer comprising a third III-nitride material having a first bandgap and coupled to the barrier layer;
a second barrier layer characterized by a second bandgap and coupled to the channel layer, wherein the second bandgap is greater than the first bandgap; and
a gate region comprising a gate material disposed between the second barrier layer and a gate contact.

9. The integrated device of claim 8 wherein the gate material comprises a p-type III-nitride material.

10. The integrated device of claim 9 wherein second barrier layer comprises a p-type III-nitride material.

11. The integrated device of claim 8 wherein the gate material comprises a dielectric material.

12. The integrated device of claim 8 further comprising:
an ohmic source contact electrically coupled to the second barrier layer; and
an ohmic drain contact electrically coupled to the second barrier layer

13. The integrated device of claim 12 wherein the gate contact comprises an ohmic metal.

14. The integrated device of claim 12 wherein the ohmic source contact and the ohmic drain contact are separated along a horizontal direction.

15. The integrated device of claim 8 wherein the first III-nitride material comprises an n-type GaN substrate.

16. The integrated device of claim 8 wherein the second III-nitride material and the third III-nitride material comprise n-type GaN.

17. The integrated device of claim 8 wherein the drift region has a thickness between 1 μm and 100 μm.

18. A method for fabricating an integrated transistor and Schottky diode, the method comprising:
providing a III-nitride structure having:
a III-nitride substrate;
a first III-nitride epitaxial layer coupled to the III-nitride substrate;
a second III-nitride epitaxial layer coupled to the first III-nitride epitaxial layer;
a third III-nitride epitaxial layer coupled to the second III-nitride epitaxial layer; and
a fourth III-nitride epitaxial layer coupled to the third III-nitride epitaxial layer;
forming an insulating layer coupled to a portion of the fourth III-nitride epitaxial layer;
removing at least a portion of the fourth III-nitride epitaxial layer, at least a portion of the third III-nitride epitaxial layer, and at least a portion of the second III-nitride epitaxial layer to expose a portion of the first III-nitride epitaxial layer;
forming a first ohmic structure electrically coupled to the III-nitride substrate;
forming a source ohmic structure electrically coupled to the fourth III-nitride epitaxial layer;
forming a gate structure;
forming a drain ohmic structure electrically coupled to the fourth III-nitride epitaxial layer; and
forming a Schottky contact to the first III-nitride epitaxial layer.

19. The method of claim 18 wherein the gate structure comprises a Schottky contact to the fourth III-nitride epitaxial layer.

20. The method of claim 18 wherein the III-nitride structure further comprises a III-nitride epitaxial material disposed between the gate structure and the fourth III-nitride epitaxial layer.

21. The method of claim 20 wherein the III-nitride epitaxial material comprises p-type AlGaN.

22. The method of claim 20 wherein the gate structure comprises an ohmic metal.

23. The method of claim 18 further comprising forming a second insulating layer coupled to a portion of the insulating layer and a portion of the fourth III-nitride epitaxial structure, wherein a portion of the second insulating layer is disposed between the gate structure and the fourth III-nitride epitaxial layer.

24. The method of claim 23 wherein the gate structure comprises an ohmic metal.

25. The method of claim 18 wherein a thickness of the first III-nitride epitaxial layer is between about 1 μm and about 100 μm.
